(19) United States
(12) Patent Application Publication
(10) Pub. No.: US 2026/0068041 A1
(43) Pub. Date: Mar. 5, 2026

(54) PATTERNED SILICON-ON-INSULATOR WAFERS

(71) Applicant: Coolstar Technology, Inc., Sunnyvale, CA (US)

(72) Inventors: Hong Lin, Saratoga, CA (US); Haike Dong, San Ramon, CA (US); Xiaotong Lin, Dallas, TX (US)

(21) Appl. No.: 18/817,487

(22) Filed: Aug. 28, 2024

(51) Int. Cl. H05K 1/03; H01L 21/762

(52) U.S. Cl. CPC H05K 1/0306; H05K 2201/10053; H05K 2201/10098

(57) ABSTRACT

A patterned silicon-on-insulator (SOI) wafer includes a semiconductor substrate, an insulator layer, and a semiconductor active layer sequentially stacked in a vertical direction perpendicular to a lower surface of the semiconductor substrate. The patterned SOI wafer includes a first region and a second region adjacent to the first region in a horizontal direction parallel to the lower surface of the semiconductor substrate, the first region being configured for low-power devices and the second region being configured for high-power devices. In the second region, at least a portion of the insulator layer is removed such that the semiconductor active layer is in direct contact with the semiconductor substrate.

### FIELD

The present invention relates generally to semiconductor wafers, and more particularly to patterned silicon-on-insulator (SOI) wafers, and methods of making same.

### BACKGROUND

A radio frequency (RF) front-end module (FEM) may include a plurality of electronic circuits that are provided between an antenna and a digital baseband system of an RF system. As an example, the FEM may include, but is not limited to, an RF power amplifier (PA), a low-noise amplifier (LNA), a transmit/receive switch (SW), a band switching module, a duplexer and filter module, and an antenna tuning module. In some embodiments, the FEM may be implemented by a single package having one or more dies to thereby provide reduced form factor, improved system-level implementation for original equipment manufacturers (OEMs), reduced cost, and improved performance compared to an FEM that is implemented by several different packages.

For example, an FEM may include a PA die that is fabricated on a bulk silicon wafer, a gallium arsenide (GaAs) wafer, a silicon carbide (SiC) wafer, or a gallium nitride wafer, and the SW and LNA are fabricated on a separate GaAs wafer or silicon-on-insulator (SOI) wafer. The multiple dies including the PA, SW, and LNA are then provided on a support substrate and assembled as a single package. However, integrating multiple dies into a single FEM package may introduce increased cost-based and time resources that are employed to efficiently integrate multiple dies having different transistor and/or wafer types into an FEM package (e.g., integrating one or more heterojunction bipolar transistors (HBTs) of a PA with one or more pseudomorphic high electron mobility transistors (pHEMTs) of a SW/LNA, or integrating bulk silicon and SOI substrates).

As another example, the PA, SW, and LNA may be integrated on a single die. However, overcoming undesirable inherent physical, chemical, and electrical characteristics of the given wafer type may add significant cost and complexity to the FEM package.

### SUMMARY

One or more embodiments of the present invention provide techniques for enhancing thermal and electrical characteristics of devices on a wafer in a manner which does not add significant cost to manufacturing or degrade the performance of devices on the wafer.

In accordance with one embodiment, a patterned silicon-on-insulator (SOI) wafer includes a semiconductor substrate, an insulator layer, and a semiconductor active layer sequentially stacked in a vertical direction perpendicular to a lower surface of the semiconductor substrate. The patterned SOI wafer includes a first region and a second region adjacent to the first region in a horizontal direction parallel to the lower surface of the semiconductor substrate, the first region being configured for low-power devices and the second region being configured for high-power devices. In the second region, at least a portion of the insulator layer is removed such that the semiconductor active layer is in direct contact with the semiconductor substrate.

In accordance with another embodiment, a SOI wafer includes a low-power circuit region includes a semiconductor substrate, an insulator layer on the semiconductor substrate, an insulating spacer on the insulator layer, and a semiconductor active layer on the insulator layer. The semiconductor substrate, the insulator layer, and the semiconductor active layer extend in a horizontal direction parallel to a lower surface of the semiconductor substrate. The insulating spacer extends in a vertical direction perpendicular to the lower surface of the semiconductor substrate. A high-power circuit region including the semiconductor substrate and the semiconductor active layer is directly on the semiconductor substrate.

In accordance with another embodiment, a patterned silicon-on-insulator (SOI) wafer includes a semiconductor substrate, an insulator layer, and a semiconductor active layer sequentially stacked in a vertical direction perpendicular to a lower surface of the semiconductor substrate. The patterned SOI wafer includes a first region and a second region adjacent to the first region in a horizontal direction parallel to the lower surface of the semiconductor substrate, the first region being configured for low-power devices and the second region being configured for high-power devices. In the second region, at least a portion of the insulator layer is removed such that the semiconductor active layer is in direct contact with the semiconductor substrate. A low noise amplifier is in the first region and configured to generate a first output power. A radio frequency (RF) power amplifier is in the second region and configured to generate a second output power. A switch is in the first region and electrically connected to the low noise amplifier and the RF power amplifier.

Techniques of the present inventive concept can provide substantial beneficial technical effects. By way of example only and without limitation, aspects according to embodiments of the present disclosure may provide one or more of the following advantages, among other benefits:
facilitates the integration of low-power circuitry requiring a high degree of noise isolation, characteristic of an SOI wafer, with high-power circuitry requiring superior thermal transfer characteristic of a bulk silicon wafer; and
easily integrates with existing semiconductor device fabrication processes.

These and other features and advantages of the present invention will become apparent from the following detailed description of illustrative embodiments thereof, which is to be read in connection with the accompanying drawings.

### BRIEF DESCRIPTION OF THE DRAWINGS

The following drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1A is a block diagram depicting at least a portion of a front-end module (FEM) circuit;

FIG. 1B is a schematic cross-sectional view depicting at least a portion of an FEM package implemented using a plurality of wafers on a support substrate;

FIG. 1C is a schematic cross-sectional view depicting at least a portion of an FEM package implemented using one wafer on a support substrate;

FIG. 2 is a schematic cross-sectional view depicting at least a portion of an exemplary wafer having enhanced thermal and electrical characteristics, according to one or more embodiments of the invention;

FIG. 3 depicts at least a portion of an exemplary method for fabricating the wafer illustrated in FIG. 2, according to one or more embodiments of the invention;

FIGS. 4A, 4B, 4C, 4D, and 4E are schematic cross-sectional views depicting various intermediate processes of fabricating the wafer illustrated in FIG. 2, according to one or more embodiments of the invention;

FIG. 5A is a schematic cross-sectional view depicting at least a portion of another exemplary wafer having enhanced thermal and electrical characteristics, according to an embodiment of the invention;

FIG. 5B is a schematic cross-sectional view depicting at least a portion of an additional exemplary wafer having enhanced thermal and electrical characteristics, according to one or more embodiments of the invention;

FIG. 6 depicts at least a portion of an exemplary method for fabricating the wafer illustrated in FIG. 5A, according to one or more embodiments of the invention;

FIGS. 7A, 7B, and 7C are schematic cross-sectional views depicting various intermediate processes of fabricating the wafer illustrated in FIG. 5A, according to one or more embodiments of the invention;

FIG. 8 depicts at least a portion of an exemplary method for fabricating the wafer illustrated in FIG. 5B, according to one or more embodiments of the invention; and

FIGS. 9A, 9B, 9C, 9D, 9E, and 9F are schematic cross-sectional views depicting various intermediate processes of fabricating the wafer illustrated in FIG. 5B, according to embodiments of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of the present invention will be described herein in the context of illustrative patterned SOI wafers, and methods of forming such wafers, having improved thermal and electrical characteristics thereof relative to conventional SOI wafers. It is to be appreciated, however, that the invention is not limited to the specific methods and/or devices illustratively shown and described herein. Rather, aspects of the present disclosure relate more broadly to techniques for providing enhanced thermal transfer in an SOI-based semiconductor structure. Moreover, it will become apparent to those skilled in the art given the teachings herein that numerous modifications can be made to the embodiments shown that are within the scope of the claimed invention. That is, no limitations with respect to the embodiments shown and described herein are intended or should be inferred.

Although the overall fabrication method and structures formed thereby, as will be described in further detail herein below, are entirely novel, certain individual processing steps required to implement a portion or portions of the method(s) according to one or more embodiments of the invention may utilize conventional semiconductor fabrication techniques and/or conventional semiconductor fabrication tooling. These techniques and tooling will already be familiar to one having ordinary skill in the relevant arts. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are hereby incorporated by reference herein in their entirety. It is emphasized that while some individual processing steps are set forth herein, those steps are merely illustrative and one skilled in the art may be familiar with several equally suitable alternatives that would also fall within the scope of the present inventive concept.

It is to be understood that the various layers and/or regions shown in the accompanying figures are not necessarily drawn to scale. Furthermore, one or more semiconductor layers of a type commonly used in such integrated circuit devices may not be explicitly shown in a given figure for economy of description. This does not imply, however, that the semiconductor layer(s) and/or region(s) not explicitly shown are omitted in the actual integrated circuit device.

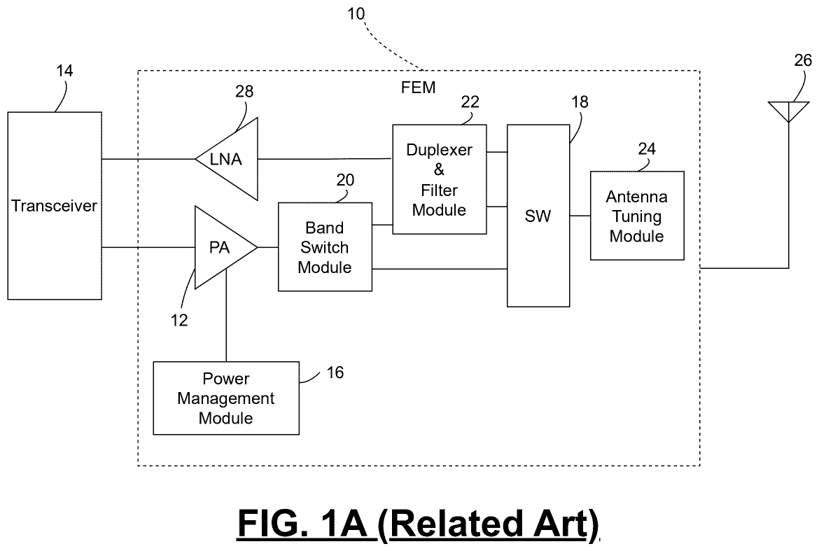

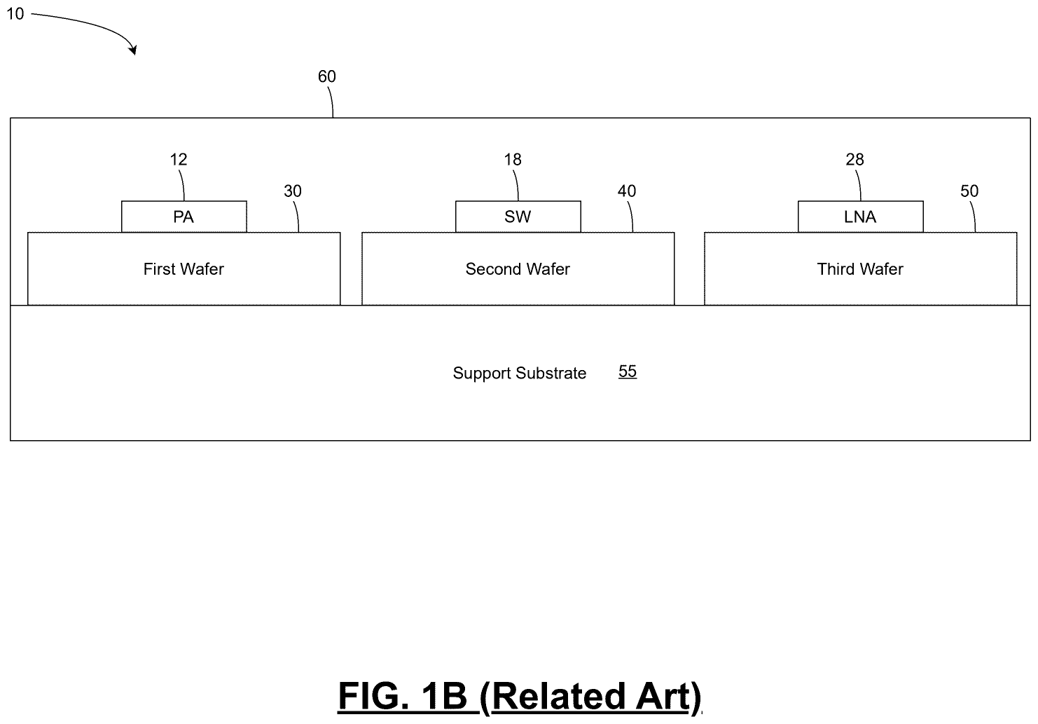

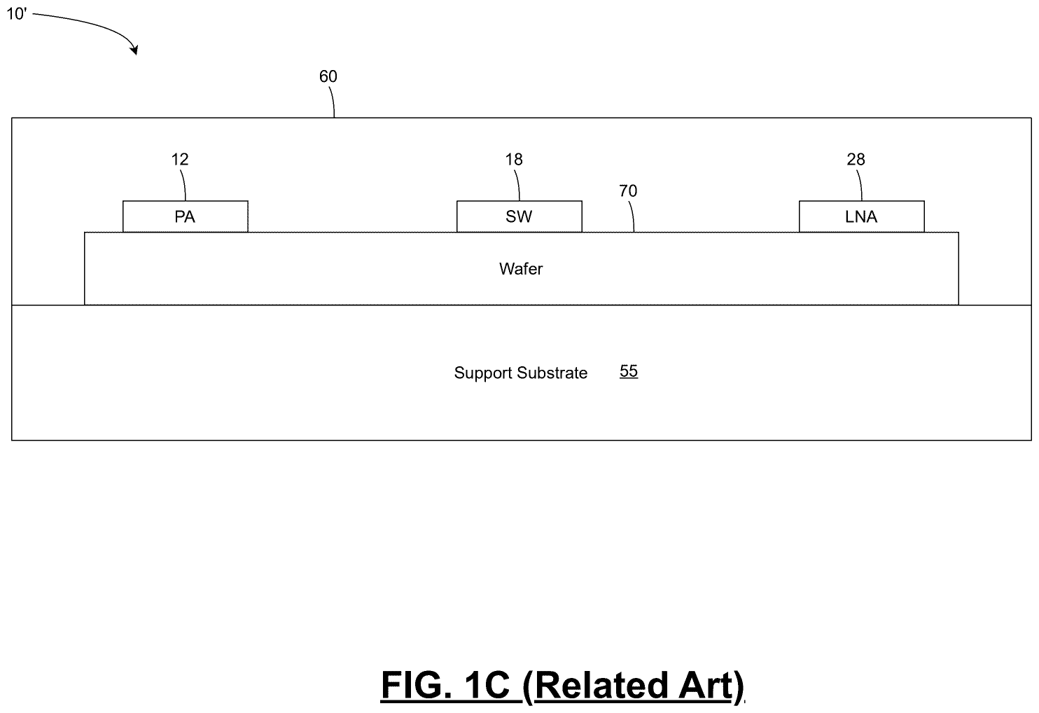

FIG. 1A is a block diagram depicting an example standard RF FEM 10. As discussed above, the FEM is generally defined as everything between the antenna and the digital baseband system. The FEM 10 includes a power amplifier (PA) 12 having an input coupled with a transceiver 14, either directly or through an impedance matching network (not explicitly shown), and being adapted to receive a transmit input signal (TX IN). It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The FEM 10 may include a power management module 16. The power management module 16, which may include a direct current (DC)-DC converter and associated circuitry, converts an external DC system supply to a suitable supply voltage for powering the PA 12. An amplified output signal generated by the PA 12 is supplied to a transmit/receive switch (SW) 18, either directly or via a band switching module 20 and/or a duplexers and filters module 22. The term “and/or,” as used herein, is intended to include any and all combinations of one or more of the associated listed items. An output of the transmit/receive switch 18 may be fed to an antenna tuning module 24 and then supplied to an antenna 26 for transmission of the amplified output signal. It should be understood that the power management module 16, the band switching module 20, and/or the duplexers and filters module 22 may be optional, and therefore may be omitted from the FEM 10 in some embodiments.

A receive signal path in the FEM 10 includes the antenna 26, the antenna tuning module 24, the transmit/receive switch 18, and the duplexers and filters module 22. An output of the duplexers and filters module 22 is supplied to an input of an LNA 28 that is adapted to amplify the received signal before presenting it to the transceiver 14. This arrangement allows certain elements of the FEM 10 to be shared by both the transmit and receive signal paths, such as the duplexers and filters module 22 and antenna 26.

In some embodiments, the PA 12 may be configured to output a first power level, the LNA 28 may be configured to output a second signal at a second power level that is less than the first power level, and the transmit/receive switch 18 may be configured to direct the RF signal to the PA 12 or to the LNA 28 by controlling the transmit signal path and/or the receive signal path.

While an example of the FEM 10 is shown in FIG. 1A, it should be understood that the FEM 10 may be configured using other circuit topologies or include other components that are omitted from FIG. 1A for brevity.

FIG. 1B is a schematic cross-sectional view depicting at least a portion of the FEM 10 shown in FIG. 1A. In some embodiments, the PA 12 is provided on a first wafer 30, the transmit/receive switch 18 is provided on a second wafer 40, and the LNA 28 is provided on a third wafer 50. The first wafer 30 may include, but is not limited to, a bulk silicon wafer, a GaAs wafer, a SiC wafer, or a gallium nitride wafer. The second wafer 40 and the third wafer 50 may be different from each other and may include, for example, a GaAs wafer or SOI wafer. The first wafer 30, the second wafer 40, and third wafer 50 are provided on a support substrate 55 and are at least partially encapsulated by an encapsulant 60 (e.g., a resin) in forming a packaged FEM 10.

While not explicitly shown, the FEM 10 may include various leads and/or interconnection elements (e.g., bond wires, through-silicon vias (TSVs), solder bumps, interconnect structures, etc.) that facilitate an electrical connection between the separate FEM circuit components (e.g., PA 12, SW 18, LNA 28), or between the FEM 10 and/or one or more external components. As discussed above, integrating the PA 12, the transmit/receive switch 18, and the LNA 28 into a single package may introduce increased cost-based and time resources that are employed to efficiently integrate the different transistor types of the PA 12, the transmit/receive switch 18, the LNA 28 (e.g., a heterojunction bipolar transistor (HBT), a pseudomorphic high electron mobility transistor (pHEMT), and/or a metal-oxide-semiconductor field effect transistor (MOSFET)), and/or the different wafer types of the first wafer 30, the second wafer 40, and the third wafer 50.

FIG. 1C is a schematic cross-sectional view depicting at least a portion of an example FEM 10′. FEM 10′ is similar to FEM 10 illustrated in FIGS. 1A-1B, except that the first wafer 30, the second wafer 40, and the third wafer 50 are replaced with a single wafer 70, such as an SOI wafer; that is, the PA 12, transmit/receive switch 18, and LNA 28 may be formed on the same wafer 70. However, the SOI wafer 70 may not have a thermal conductivity (e.g., about 1.4 W/m·K for a silicon dioxide insulating layer) that is sufficient to effectively dissipate heat generated by, for example, the PA 12, thereby increasing the likelihood of device failure due to higher operating junction temperatures.

Aspects of the present inventive concept address one or more problems of integrating different wafer types and/or transistor types of the FEM in a single wafer. More particularly, in accordance with one or more embodiments described in further detail herein below, the FEM includes a patterned SOI wafer that includes a semiconductor substrate, an insulator layer, and a semiconductor active layer sequentially stacked in a vertical direction perpendicular to an upper surface of the silicon substrate. The patterned SOI wafer includes a first region and a second region that are laterally adjacent to each other, where the first region is configured for low-power circuits and devices (e.g., the transmit/receive switch 18, the LNA 28, and/or passive devices such as capacitors or inductors), and where the second region is configured for high-power circuits and devices (e.g., the PA 12). In the second region of the patterned SOI, at least a portion of the insulator layer of the patterned SOI wafer is removed such that a semiconductor active layer directly contacts the semiconductor substrate. Accordingly, the patterned SOI wafer may employ the advantages of conventional SOI wafers for operating the transmit/receive switch 18, the LNA 28, and other relatively low-power and low-noise devices of the FEM 10 in one region while providing substantially enhanced thermal conductivity and dissipation of heat generated by the PA 12 to an external environment due to the direct contact between the semiconductor active layer and the semiconductor substrate in the second region.

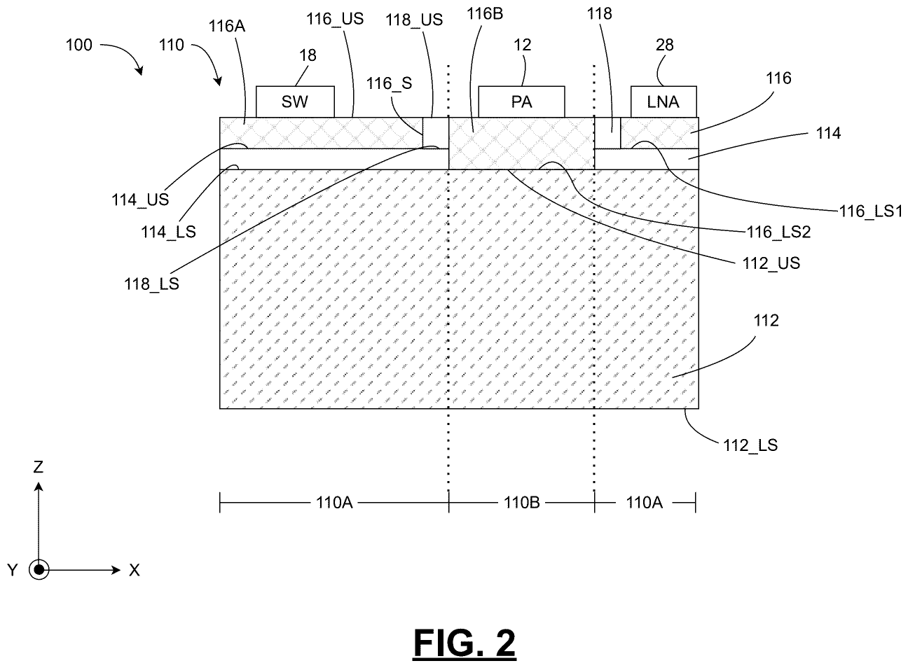

Aspects of the present inventive concept will now be described in further detail with reference to FIGS. 2, 3, 4A-4D, 5A-5B, 6, and 7A-7C.

FIG. 2 depicts a schematic cross-sectional view of at least a portion of an exemplary FEM package 100 comprising a patterned SOI wafer 110, in accordance with one or more embodiments of the invention. Although not explicitly shown (but implied), it should be understood that the FEM package 100 may include a support substrate (e.g., the support substrate 55 in FIGS. 1B and 1C), an encapsulant (e.g., the encapsulant 60 in FIGS. 1B and 1C), and/or other circuits of the FEM package 100 described above.

In some embodiments, the patterned SOI wafer 110 may include one or more first regions 110A (also referred to herein as low-power circuit regions 110A) and at least one second region 110B (also referred to herein as high-power circuit region 110B) that may be between and adjacent to the first regions 110A in a first horizontal direction that is parallel to an upper surface of the patterned SOI wafer 110 (e.g., the X-direction). It is to be understood that the second region 110B need not be disposed between adjacent first regions 110A. For example, in some embodiments where only one first region 110A is provided, the second region 110B may be laterally adjacent to the first region 110A. A thermal conductivity of the second region 110B (e.g., bulk silicon at about 156 W/m·K) may be greater than a thermal conductivity of the first regions 110A (e.g., a buried oxide layer at about 1.4 W/m·K). Accordingly, the transmit/receive switch 18, the LNA 28, and/or other relatively low-power circuits and devices of the FEM package 100 (e.g., circuits and/or devices that have a relatively lower heat output) may be formed in the first regions 110A of the patterned SOI wafer 110. The PA 12 and/or other relatively high-power circuits and devices of the FEM package 100 (e.g., circuits and/or devices that have a relatively higher heat output) may be formed in the second region 110B of the patterned SOI wafer 110.

In some embodiments, the patterned SOI wafer 110 may include a semiconductor substrate 112, an insulator layer 114, a semiconductor (e.g., silicon) active layer 116 and, optionally one or more insulating spacers 118. In the first regions 110A, the semiconductor substrate 112, the insulator layer 114, and the semiconductor active layer 116 may be stacked in a vertical direction (e.g., Z-direction) perpendicular to the upper surface of the patterned SOI wafer 110 such that the insulator layer 114 is between the semiconductor active layer 116 and the semiconductor substrate 112. Likewise, in the first regions 110A, the semiconductor substrate 112, the insulator layer 114, and the insulating spacer 118 may be stacked in the vertical direction such that the insulator layer 114 is between and contacts the insulating spacer 118 and the semiconductor substrate 112. In the second region 110B, at least a portion of the insulator layer 114 is removed such that the semiconductor active layer 116 is in direct contact with the semiconductor substrate 112.

The semiconductor substrate 112 is configured to physically support the insulator layer 114, the semiconductor active layer 116, the insulating spacer 118, and any active electrical circuits, devices and/or electrical connections formed in the semiconductor active layer 116 (e.g., the PA 12, the SW 18, and the LNA 28). The semiconductor substrate 112 may also be configured to dissipate heat generated by, for example, the PA 12, the transmit/receive switch 18, and the LNA 28. As an example, the semiconductor substrate 112 may be a silicon substrate having any suitable thickness in the vertical direction, crystal orientation and/or material type (e.g., a monocrystalline silicon, silicon carbide, etc.), dopant concentration and/or conductivity type, and/or resistivity (e.g., a resistance value that reduces the RF signal loss for the PA 12 to an acceptable or threshold value) to perform the functionality described herein.

The insulator layer 114 (e.g., a buried oxide (BOX) layer) is configured to electrically isolate at least a portion of the semiconductor substrate 112 and the semiconductor active layer 116 from each other. As an example, the insulator layer 114 electrically isolates the semiconductor substrate 112 and the semiconductor active layer 116 in the first regions 110A. In some embodiments, the insulator layer 114 may comprise silicon dioxide and may have any suitable thickness in the vertical direction, which may reduce the parasitic capacitance and leakage currents between the semiconductor substrate 112 and the semiconductor active layer 116 in the first regions 110A.

The semiconductor active layer 116, which may include a first portion 116A in the first region 110A and a second portion 116B in the second region 110B, is configured to physically support the active electrical devices thereon (e.g., the PA 12, the SW 18, and the LNA 28) and may include silicon and/or another semiconductor material. The semiconductor active layer 116 may be a relatively thin film having a thickness in the vertical direction that is less than a thickness of the semiconductor substrate 112 in the vertical direction. The semiconductor active layer 116 and the semiconductor substrate 112 may have a same or different material (e.g., both of the semiconductor active layer 116 and the semiconductor substrate 112 may include silicon), crystal orientation and/or type, dopant concentration and/or type (e.g., the dopant concentration of the semiconductor substrate 112 is less than the dopant concentration of the semiconductor active layer 116), and/or resistivity to perform the functionality described herein.

In one or more embodiments, the semiconductor substrate 112 may comprise, for example, a single crystal silicon semiconductor substrate that has a resistivity of about 500-1000 ohms·cm, which corresponds to a doping concentration of about 10¹³ atoms/cm³. Likewise, the semiconductor active layer 116 may be doped with n-type and/or p-type impurities of a prescribed doping concentration level. The semiconductor active layer 116 may include both n-type areas (e.g., wherein n-type transistors may be formed) and p-type areas (e.g., wherein p-type transistors may be formed). The doping concentration level of the semiconductor active layer 116 may be more than the doping concentration level of the semiconductor substrate 112. The semiconductor substrate 112 may be relatively thick in some embodiments (e.g., about 50 μm-150 μm or more). It will be appreciated that the thickness of the various layers and/or structures of the patterned SOI wafer 110 may not be shown to scale in order to provide enhanced clarity of the description.

The insulating spacer 118, when used, may be configured to electrically isolate the first portion 116A of the semiconductor active layer 116 in the first region 110A from the second portion 116B of the semiconductor active layer in the second region 110B. Accordingly, the insulating spacer 118 is further configured to enhance noise isolation and reduce leakage currents between the first portion 116A of the semiconductor active layer 116 and other regions of the patterned SOI wafer 110 (and thus improve the signal-to-noise ratio of the circuits thereon, such as the LNA 28). In some embodiments, the insulating spacer 118 may comprise the same material as the insulator layer 114 or the insulating spacer 118 may comprise a different material than the insulator layer 114. As an example, the insulating spacer 118 may include an oxide film (e.g., silicon dioxide), a nitride film, an oxynitride film, or a combination thereof, although embodiments are not limited thereto. In one or more embodiments, the insulating spacer 118 may be formed as a contiguous extension of the insulator layer 114. The insulating spacer 118 may have any thickness in the horizontal direction (e.g., the X-direction) and/or the vertical direction (e.g., the Z-direction) suitable for electrically isolating the first portion 116A of the semiconductor active layer 116 and the second portion 116B of the semiconductor active layer 116. In some embodiments, the insulating spacer 118 may have a thickness in the vertical direction (e.g., the Z-direction) that is greater (or less) than a thickness of the insulator layer 114 in the vertical direction.

In some embodiments, the semiconductor substrate 112 comprises a lower surface 112_LS and an upper surface 112_US opposite to the lower surface 112_LS. The insulating layer 114 comprises a lower surface 114_LS and an upper surface 114_US opposite to the lower surface 114_LS. The insulating spacer 118 comprises a lower surface 118_LS and an upper surface 118_US opposite to the lower surface 118_LS. The first portion 116A of the semiconductor active layer 116 includes a first lower surface 116_LS1 that is separated from the lower surface 112_LS of the semiconductor substrate 112 by a first distance in the vertical direction. The second portion 116B of the semiconductor active layer 116 includes a second lower surface 116_LS2 that is separated from the lower surface 112_LS of the semiconductor substrate 112 by a second distance in the vertical direction that is less than the first distance. Each of the first and second portions 116A, 116B of the semiconductor active layer 116 includes an upper surface 116_US that is opposite to each of the first and second lower surfaces 116_LS1, 116_LS2. The upper surface 116_US of each of the first and second portions 116A, 116B of the semiconductor active layer 116 may be horizontally coplanar with one another.

In one or more embodiments, the second lower surface 116_LS2 of the semiconductor active layer 116 may or may not be horizontally coplanar with the upper surface 112_US of the semiconductor substrate 112 and the lower surface 114_LS of the insulator layer 114. The first lower surface 116_LS1 of the semiconductor active layer 116 may be horizontally coplanar with the upper surface 114_US of the insulator layer 114 and the lower surface 118_LS of the insulating spacer 118. An upper surface 118_US of the insulating spacer 118 may be horizontally coplanar with an upper surface 116_US of both portions 116A, 116B of the semiconductor active layer 116.

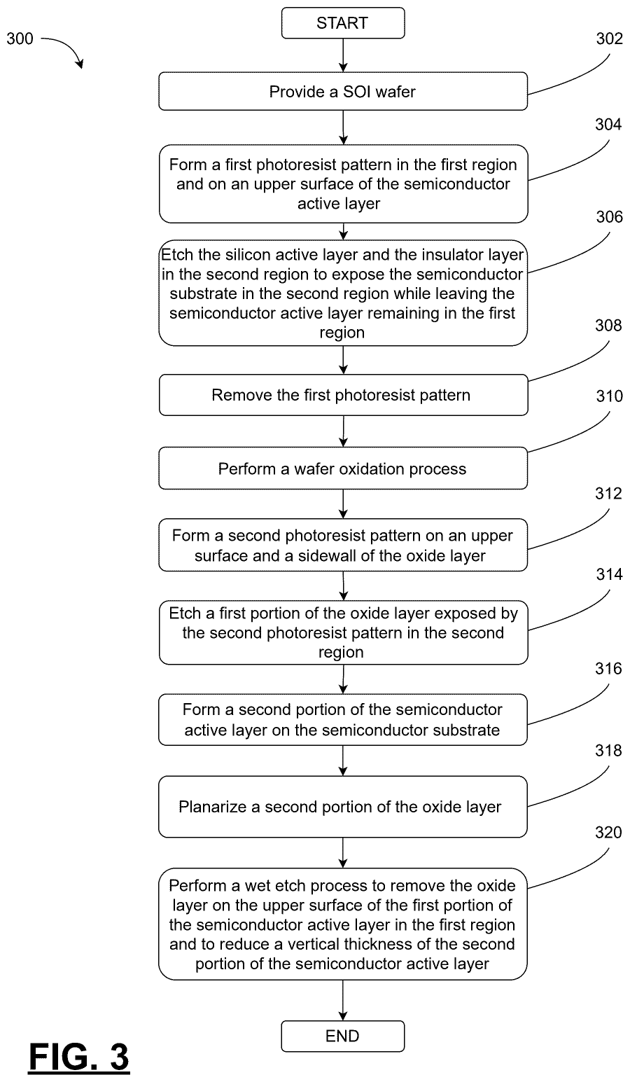

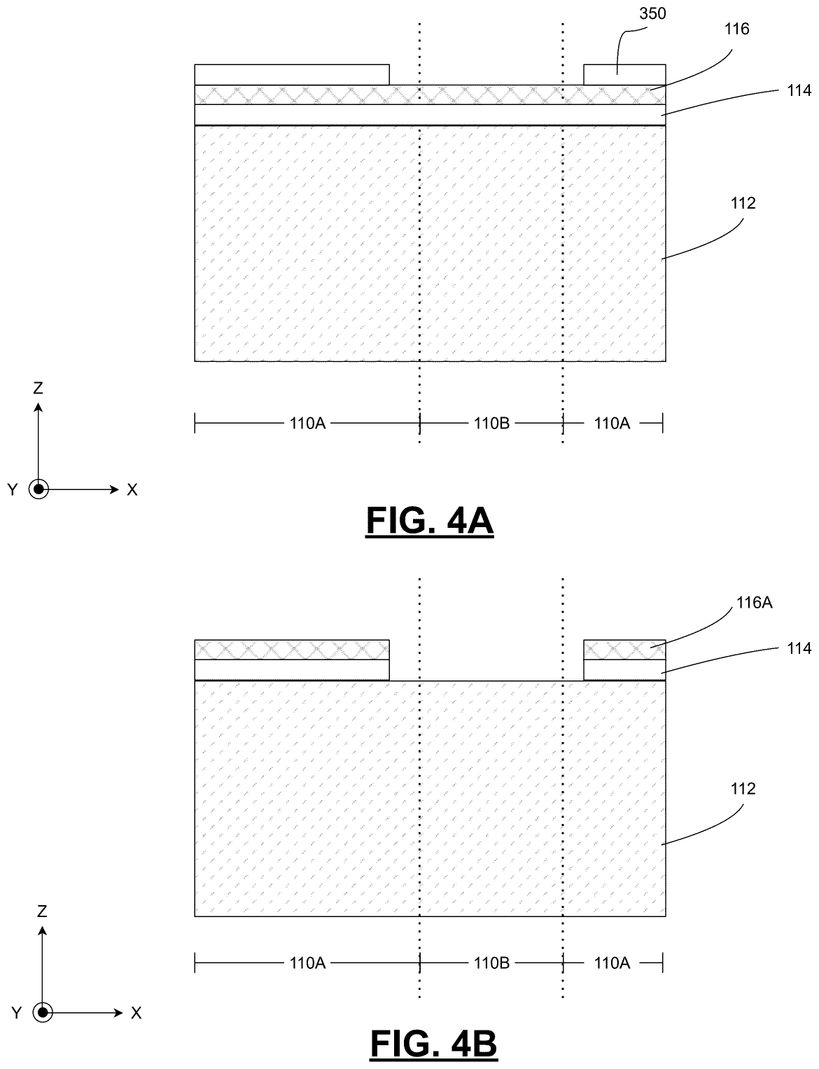

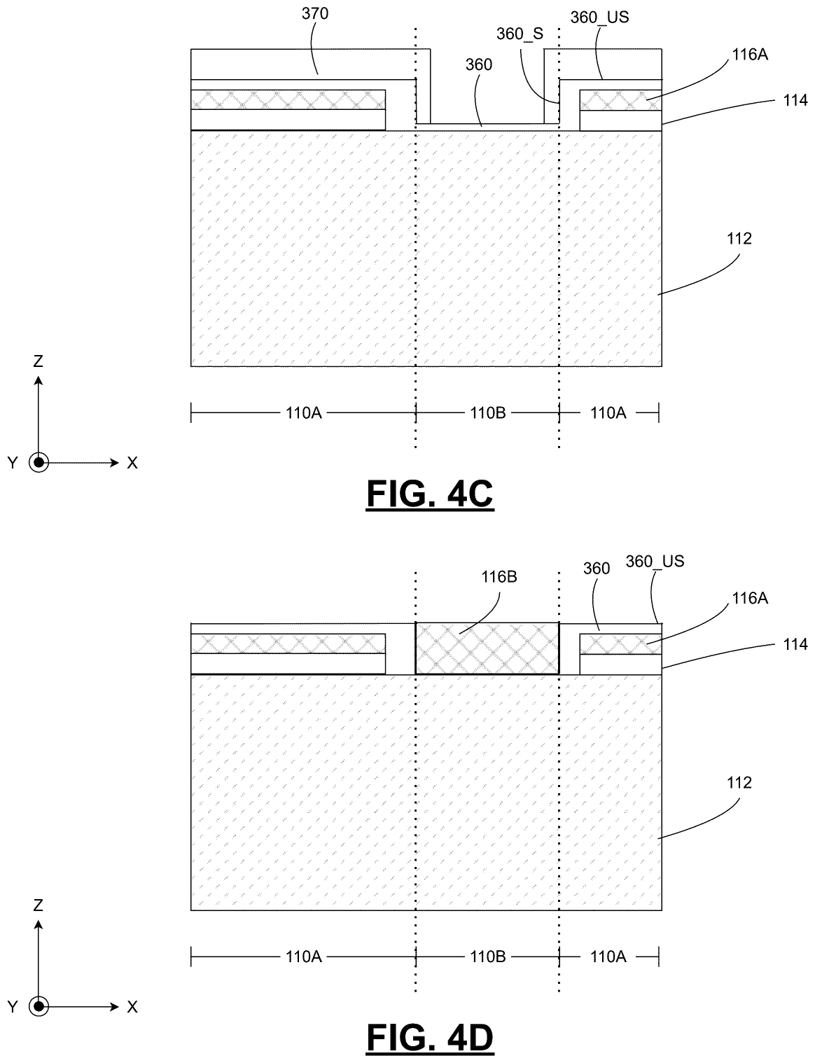

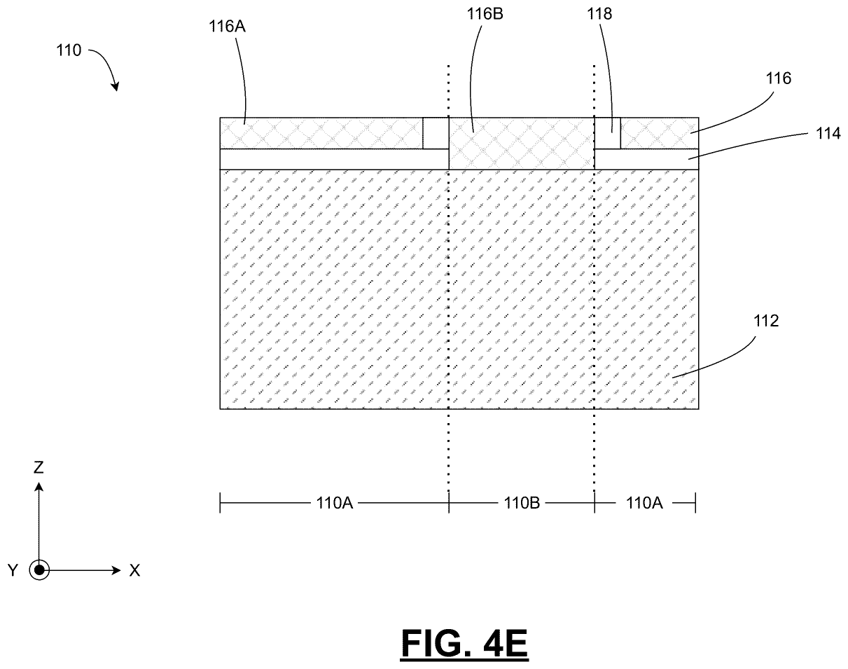

An example method of fabricating the patterned SOI wafer 110 will now be described with reference to FIGS. 3 and 4A-4E, which respectively illustrate a flowchart of an exemplary method 300 and schematic cross-sectional views depicting various intermediate processes of fabricating the patterned SOI wafer 110 depicted in FIG. 2, according to one or more embodiments. It should be understood that certain steps may not be performed in various embodiments, and the order of the steps for fabricating the patterned SOI wafer 110 are not limited to the examples illustrated and described herein.

Referring to FIGS. 3 and 4A, at step 302, the exemplary method 300 may include providing an SOI wafer comprising the semiconductor substrate 112, the insulator layer 114, and the semiconductor active layer 116 sequentially stacked in the vertical direction and extending horizontally (e.g., the X-direction and/or Y-direction) in both the first and second regions 110A, 110B. At step 304, the method 300 may include forming a first photoresist pattern 350 on an upper surface of the semiconductor active layer 116. Forming the first photoresist pattern 350 may include depositing a layer of photoresist material on the upper surface of the wafer and, using standard photolithography of the photoresist material layer, light exposure and development, forming an opening in the photoresist material that exposes the semiconductor active layer 116 in at least the second region 110B and a portion of the semiconductor active layer 116 in the first regions 110A proximate the second region 110B of the semiconductor active layer. The term “exposes” (or “exposed,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. In one or more embodiments, the first photoresist pattern 350 expose only a portion of the semiconductor active layer 116 in the first regions 110A to enable the formation of the insulating spacer 118, as described below in further detail. In other embodiments, the insulating spacers 118 may be formed entirely within the second region 110B, and therefore the first photoresist pattern 350 may cover (i.e., on or over) the entire semiconductor active layer 116 in the first regions 110A. The first photoresist pattern 350 may be deposited on the semiconductor active layer 116 using known processes, such as a spin coating process.

Referring to FIGS. 3 and 4B, at step 306, the method 300 may include etching (e.g., using anisotropic wet or dry etching, among other known etching techniques) the semiconductor active layer 116 and the insulator layer 114 in the second region 110B to expose the semiconductor substrate 112 in the second region 110B, leaving the semiconductor active layer 116 remaining in the first region 110A so as to form a first portion 116A of the semiconductor active layer 116. At step 308, the method 300 includes removing the first photoresist pattern 350.

Referring to FIGS. 3 and 4C, at step 310, the method 300 may include performing a wafer oxidation process, whereby an oxide layer 360 is formed on the upper surface of the wafer, including the semiconductor substrate 112 in the second region 110B and in a portion of the first regions 110A proximate the second region 110B. A silicon wafer forms an oxide layer when it is exposed to oxygen in the air or in other chemicals. There are a variety of known oxidation methods, such as thermal oxidation and plasma-enhanced chemical vapor deposition (PECVD). Among them, most widely used is the thermal oxidation process, which may be performed at temperatures of about 800-1200° C. to form a thin, uniform silicon dioxide layer. The oxide layer 360 may include, for example, a same material as the insulator layer 114 (e.g., silicon dioxide). At step 312, the method 300 may include forming a second photoresist pattern 370 on an upper surface 360_US of the oxide layer 360 in the first region 110A and on a sidewall 360_S of the oxide layer 360 in the second region 110B, the second photoresist pattern 370 including an opening exposing a first portion of the oxide layer 360 in the second region 110B.

Referring to FIGS. 3 and 4D, at step 314, the method 300 may include etching the first portion of the oxide layer 360 exposed by the second photoresist pattern 370 in the second region 110B, and removing the second photoresist pattern 370 thereafter. At step 316, the method 300 includes forming the second portion 116B of the semiconductor active layer 116 (e.g., by epitaxially growing the second portion 116B) on the semiconductor substrate 112 and in the second region 110B.

Referring to FIGS. 3 and 4E, at step 318, the method 300 includes performing a planarization process (e.g., CMP) to planarize the second portion 116B of the semiconductor active layer 116 in the second region 110B. At step 320, the method 300 includes performing a wet etch to remove the oxide layer 360 on the upper surface of the first portion 116A of the semiconductor active layer 116 in the first region 110A (e.g., with the upper surface of the first portion 116A of the semiconductor active layer 116 serving as a stop layer) and reducing a cross-sectional (i.e., vertical) thickness of the second portion 116B of the semiconductor active layer 116 to thereby form the insulating spacer 118 having an upper surface that may be horizontally coplanar with an upper surface of the first and second portions 116A, 116B of the semiconductor active layer 116. In this manner, the first portion 116A of the semiconductor active layer 116 in the first region 110A is spaced laterally from the second portion 116B of the semiconductor active layer 116 in the second region 110B with the insulating spacer 118 therebetween.

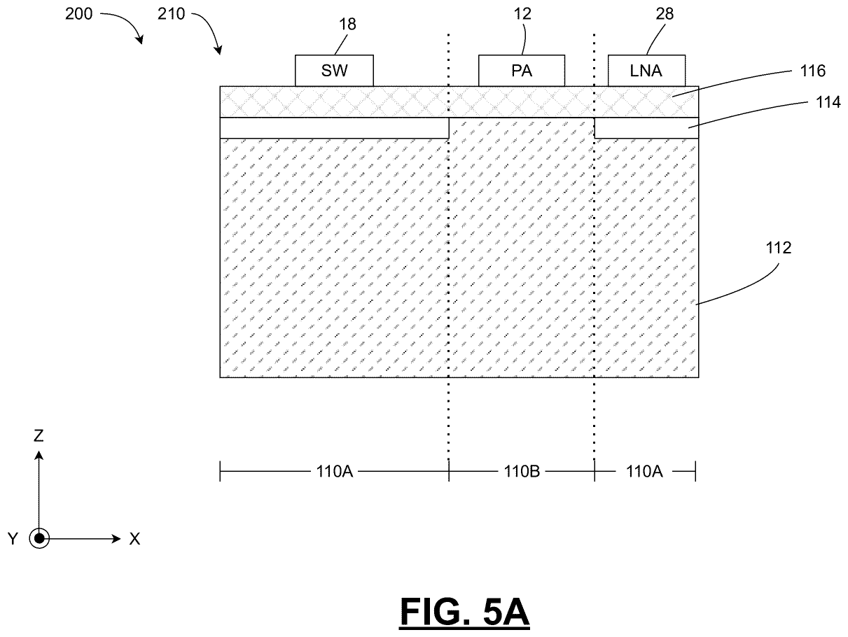

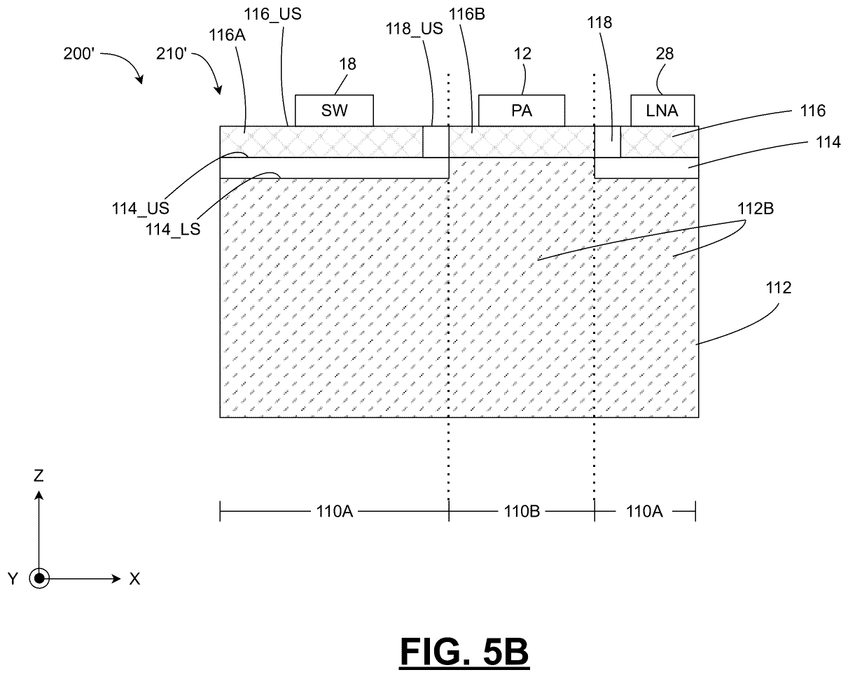

FIG. 5A depicts a schematic cross-sectional view of an FEM package 200 comprising a patterned wafer 210 in accordance with one or more embodiments of the present disclosure. Although not explicitly shown (but implied), it should be understood that the FEM package 200 may include a support substrate (e.g., the support substrate 55 in FIG. 1C), an encapsulant (e.g., the encapsulant 60 in FIG. 1C), and/or other circuits and devices of the FEM package 100 described above. The FEM package 200 and the patterned wafer 210 are similar to the FEM package 100 and the patterned SOI wafer 110, respectively, illustrated in FIG. 2, but in this embodiment, the patterned wafer 210 does not include the insulating spacer 118 separating the high-power device region (i.e., second region 110B) from the low-power device region (i.e., first region 110A) and may not be fabricated from an SOI wafer. Additionally, in this illustrative embodiment, the active region 116 of the patterned wafer 210 may be formed of the same material and at the same time as the semiconductor substrate 112, with the semiconductor substrate 112 and the active layer 116 having different doping concentrations associated therewith.

FIG. 5B depicts a schematic cross-sectional view of an FEM package 200′ comprising a patterned wafer 210′ in accordance with one or more embodiments of the present disclosure. Although not explicitly shown, it should be understood that the FEM package 200′ may include a support substrate (e.g., the support substrate 55 of FIG. 1C), an encapsulant (e.g., the encapsulant 60 of FIG. 1C), and/or other device or circuits of the FEM package 100 described above. The FEM package 200′ and the patterned wafer 210′ are similar to the FEM package 200 and the patterned wafer 210, respectively, illustrated in FIG. 5A, but in this exemplary embodiment, the patterned wafer 210′ includes the insulating spacer 118 separating the first portion 116A of the semiconductor active layer 116 in the first region 110B from the second portion 116B of the semiconductor active layer 116 in the first region 110A. In this illustrative embodiment, like the embodiment shown in FIG. 5A, the active region 116 of the patterned wafer 210′ may be formed of the same material and at the same time as the semiconductor substrate 112, only with the semiconductor substrate 112 and the active layer 116 having different doping concentrations. In one or more embodiments, a transition between the doping concentration of the second portion 116B of the semiconductor active layer 116 in the second region 110B and the doping concentration of the semiconductor substrate 112 may not form an abrupt step but rather may exhibit a gradual transition region (i.e., gradient).

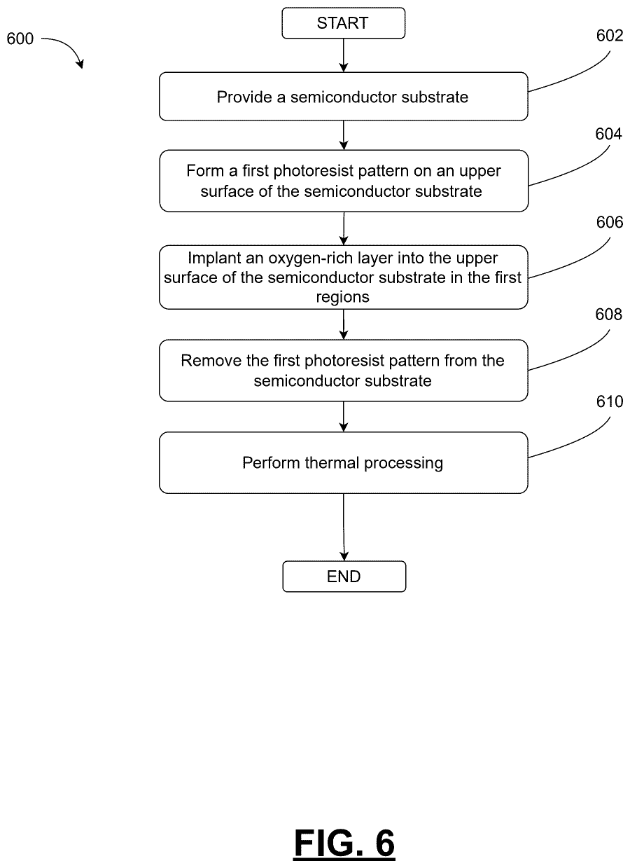

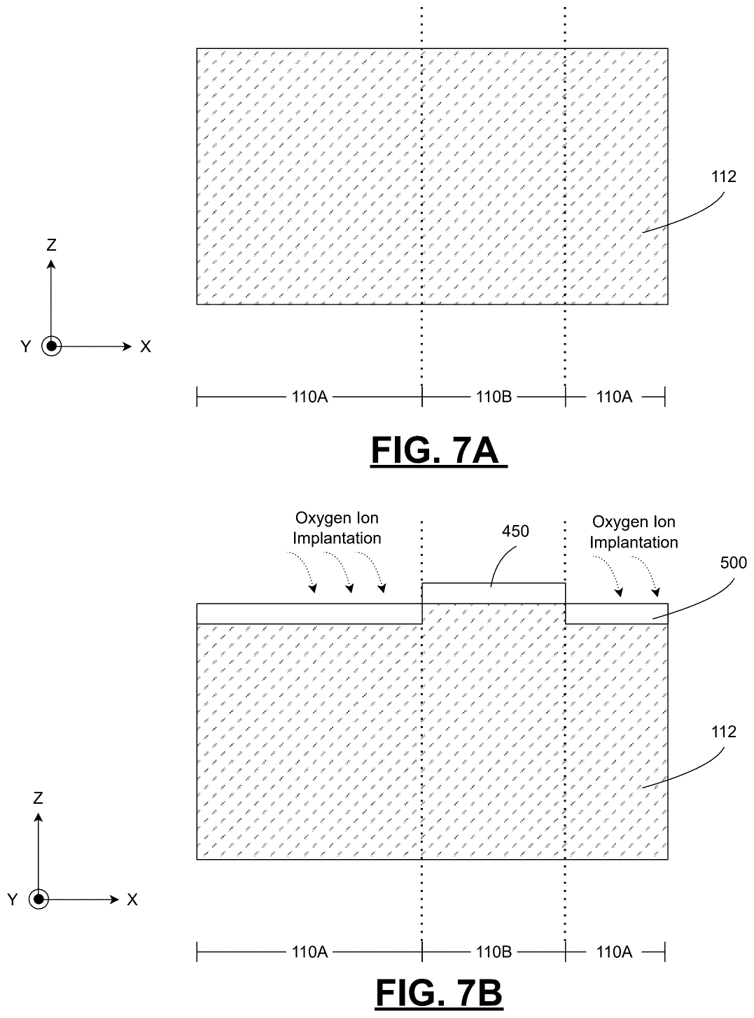

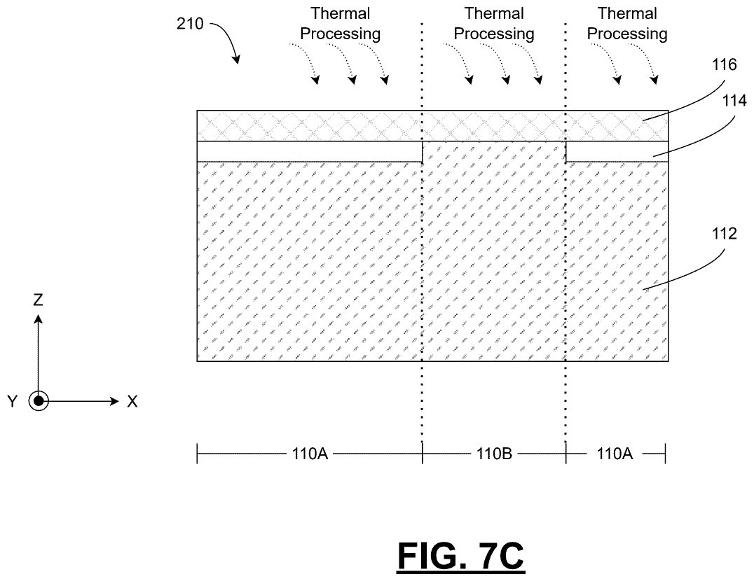

A method of fabricating the patterned wafer 210 of FIG. 5A is described below with reference to FIGS. 6 and 7A-7F, which respectively illustrate a flowchart of an exemplary method 600 and schematic cross-sectional views depicting intermediate processes of fabricating the patterned wafer 210, according to one or more embodiments. It should be understood that certain steps may not be performed in various embodiments, and the order of the steps for fabricating the patterned wafer 210 are not limited to the examples illustrated and described herein, unless noted otherwise.

Referring to FIGS. 5A, 6, and 7A, at step 602, the method 600 may include providing the semiconductor substrate 112. The semiconductor substrate 112 in this exemplary embodiment may not be provided as part of an SOI wafer. Rather, the substrate 112 may be provided as a bulk semiconductor wafer (e.g., silicon) doped with an n-type or p-type impurity of a prescribed doping concentration level. The semiconductor substrate 112, as in the illustrative method 300 shown in FIG. 3, may include one or more first regions 110A in which low-power/low-noise circuits and/or devices may be formed, and at least one second region 110B, in which high-power circuits and/or devices may be formed. In this exemplary embodiment, the second region 110B is included between adjacent first regions 110A, although embodiments are not limited to this arrangement.

Referring to FIGS. 5A, 6, and 7B, at step 604, the method 600 may include forming a first photoresist pattern 450 on an upper surface of the semiconductor substrate 112. The first photoresist pattern 450 may include openings therein to expose the semiconductor substrate 112 in the first regions 110A and to protect the semiconductor substrate 112 in the second region 110B from exposure. The first photoresist pattern 450 may overlap an entirety of the second region 110B in the vertical direction. The first photoresist pattern 450 may be formed (e.g., using a photolithographic processing technique) from a layer of photoresist material deposited on the semiconductor substrate 112 using known processes, such as a spin coating process. At step 606, the method 600 may include implanting an oxygen-rich layer 500 into the upper surface of the semiconductor substrate 112 in the first regions 110A using, for example, an oxygen ion implantation processes. Due to the presence of the first photoresist pattern 450, oxygen ions will not be implanted in the semiconductor substrate 112 in the second region 110B.

Referring to FIGS. 5A, 6, and 7C, at step 608, the method 600 may include removing the first photoresist pattern 450. At step 610, the method 600 may include performing thermal processing (e.g., annealing), whereby the wafer 210 is heated at a high temperature (e.g., 1300-1390° C. for a duration of about 4-8 hours. After thermal processing, the oxygen-rich layer 500 (FIG. 7B) will be converted to a buried silicon dioxide layer, thereby forming the insulator layer 114. The silicon layer formed above the insulator layer 114 will form the semiconductor active layer 116 of the patterned wafer 210. During the heating/annealing process, any implant-induced defects of the semiconductor substrate 112 may also be removed.

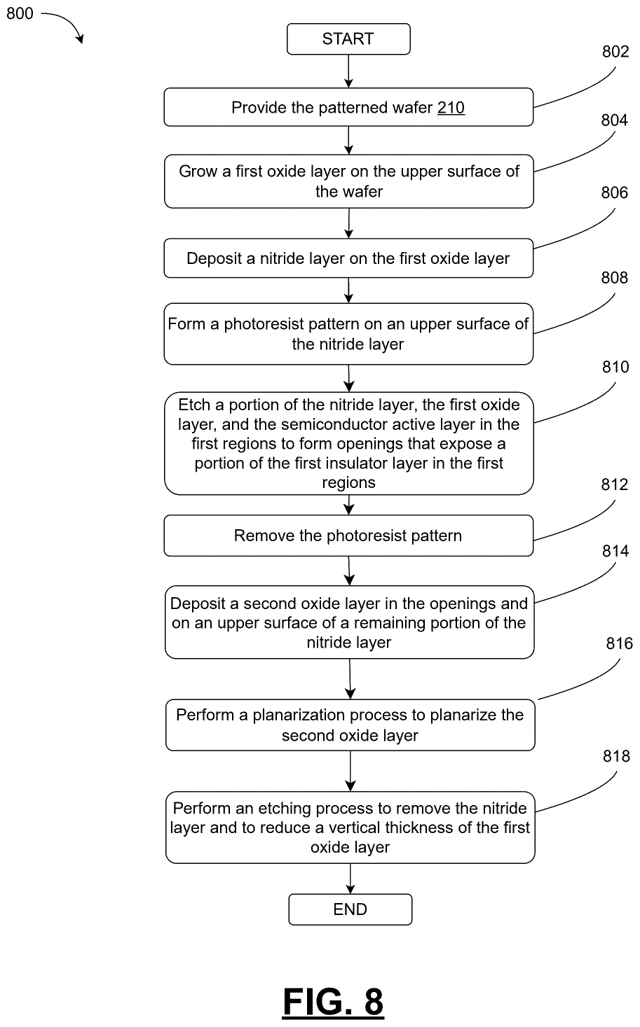

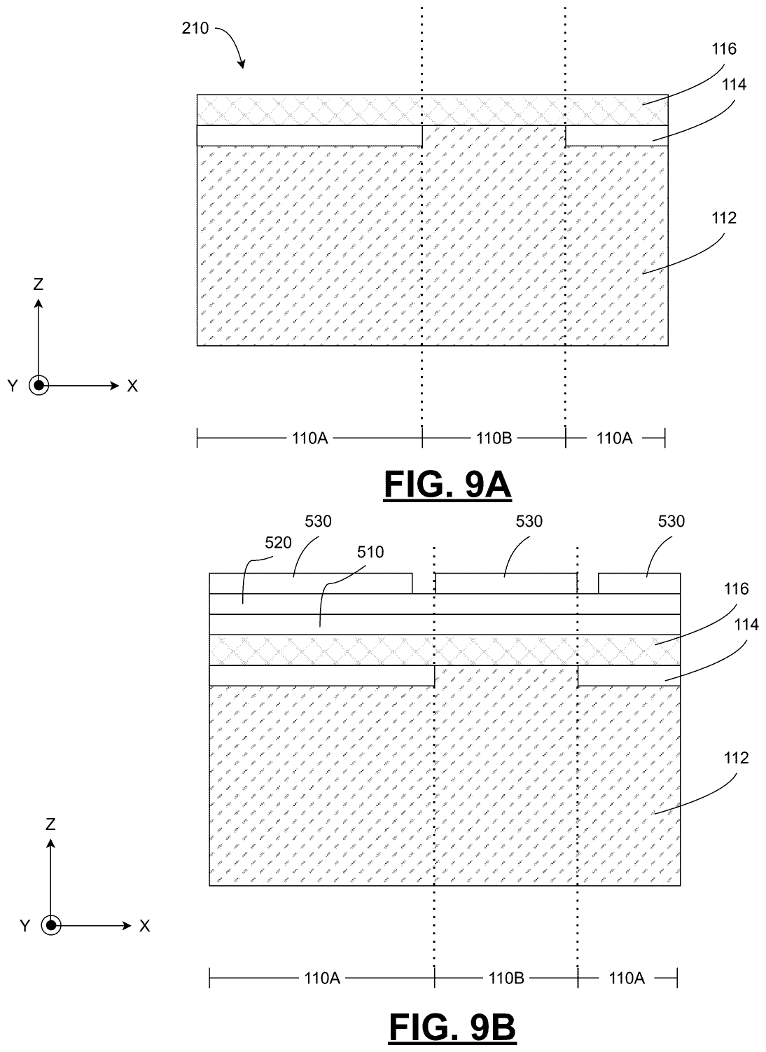

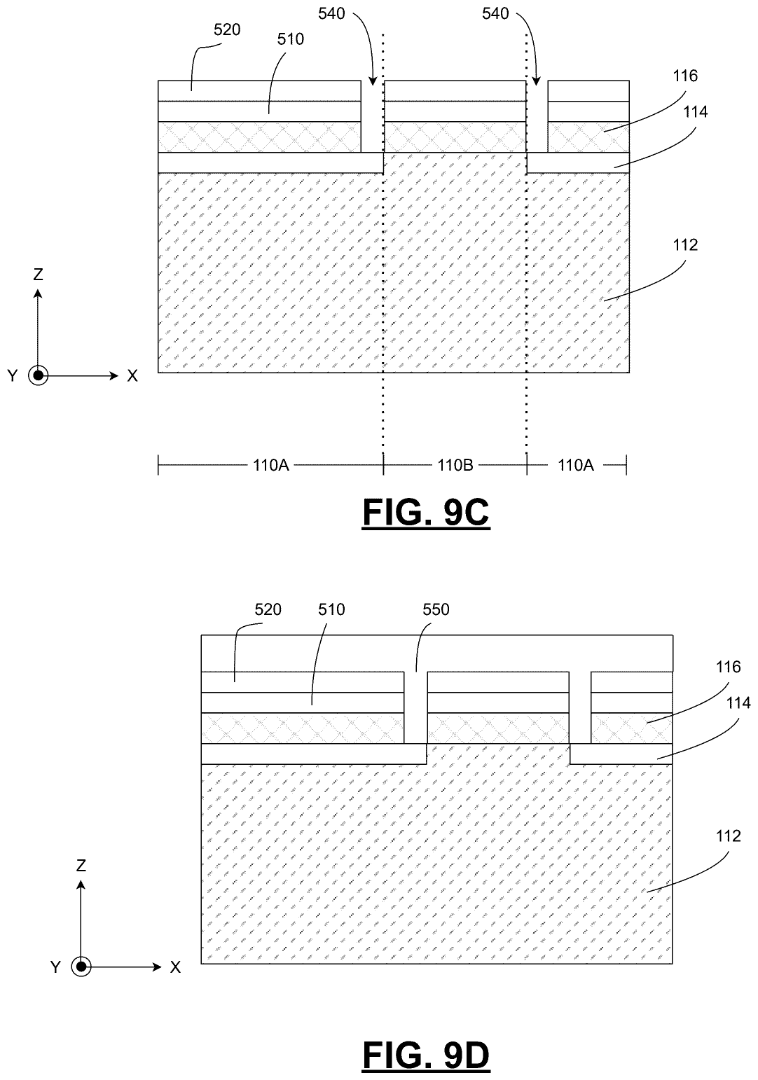

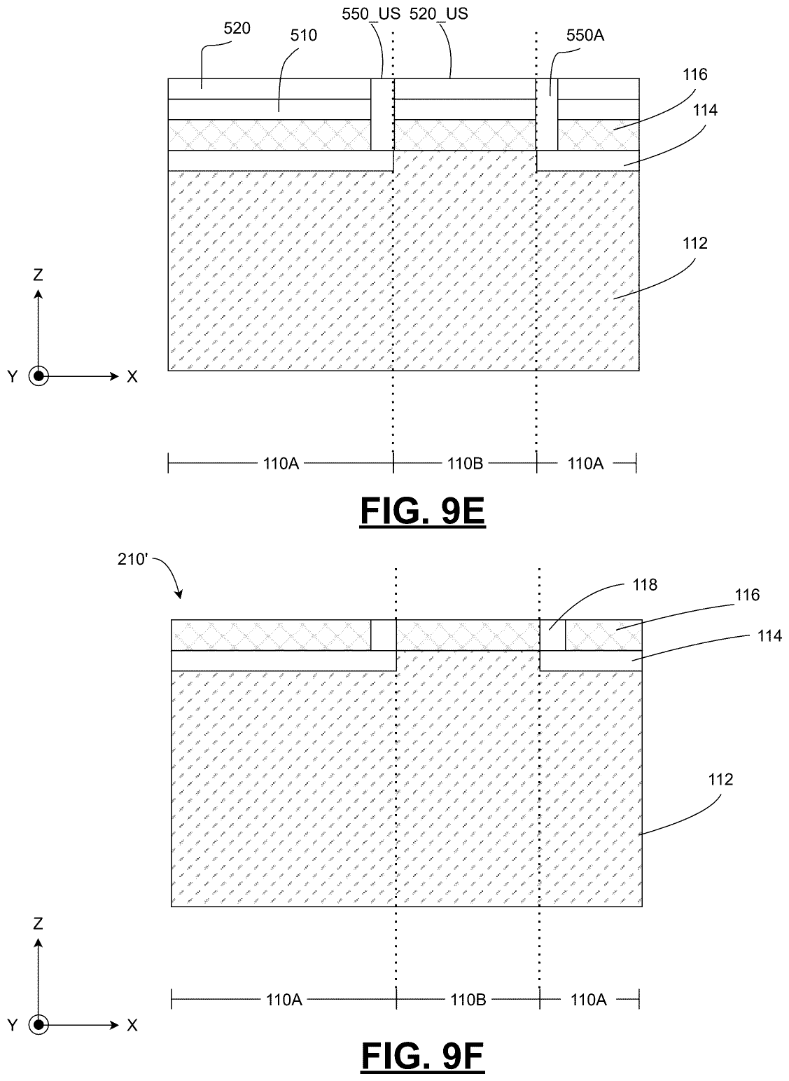

A method of fabricating the patterned wafer 210′ of FIG. 5B is described below with reference to FIGS. 8 and 9A-9F, which respectively illustrate a flowchart of an exemplary method 800 and schematic cross-sectional views depicting intermediate processes in the exemplary method 800 of fabricating the patterned wafer 210′ of FIG. 5B, according to one or more embodiments. It should be understood that certain steps may not be performed in various embodiments, and the order of the steps for fabricating the patterned wafer 210′ are not limited to the examples illustrated and described herein.

Referring to FIGS. 5B, 8 and 9A, at step 802, the method 800 may include providing the patterned wafer 210 illustrated in FIG. 5A. As an example, step 802 may include performing the method 600 described above with reference to FIGS. 6 and 7A-7C to form the patterned wafer 210 illustrated in FIG. 5A.

Referring to FIGS. 5B, 8, and 9B, at step 804, the method 800 may include growing a first oxide layer 510 on the upper surface of the wafer (e.g., an upper surface of the first portion 116A and/or the second portion 116B of the semiconductor active layer 116). In one or more embodiments, the first oxide layer 510 may be thermally grown on the upper surface of the semiconductor layer 116. At step 806, the method 800 may include depositing a nitride layer 520 including, for example, silicon nitride on the first oxide layer 510. Various known deposition methods may be employed to deposit the nitride layer 520, such as PECVD, low-pressure chemical vapor deposition (LPCVD), or physical vapor deposition (PVD). At step 808, the method may include forming a photoresist pattern 530 on an upper surface of the nitride layer 520. The photoresist pattern 530 may include openings therein to expose portions of the nitride layer 520 in the first regions 110A and may overlap an entirety of the second region 110B in the vertical direction. The photoresist pattern 530 may be formed (e.g., using a photolithographic processing technique) from a layer of photoresist material deposited on the nitride layer 520 using known processes, such as a spin coating process.

Referring to FIGS. 5B, 8, and 9C, at step 810, the method 800 may include etching (e.g., using anisotropic dry etching, among other known etching techniques) a portion of the nitride layer 520, the first oxide layer 510, and the semiconductor active layer 116 in the first region 110A (with the upper surface of the insulator layer 114 serving as a stop layer) to form openings 540 that expose a portion of the insulator layer 114 in the first region 110A. At step 812, the method 800 may include removing the photoresist pattern 530.

Referring to FIGS. 5B, 8, and 9D, at step 814, the method 800 may include depositing a second oxide layer 550 in the openings 540 and on an upper surface of a remaining portion of the nitride layer 520. In some embodiments, the second oxide layer 550 may be deposited using various known deposition methods, such as LPCVD or PECVD.

Referring to FIGS. 5B, 8, and 9E, at step 816, the method 800 includes performing a planarization process (e.g., CMP) to planarize the second oxide layer 550 such that an upper surface 550_US of remaining portions 550A of the second oxide layer 550 that are in the openings 540 and an upper surface 520_US of the nitride layer 520 are horizontally coplanar. Referring to FIGS. 5B, 8, and 9F, at step 818, the method 800 includes performing an etching process (e.g., a wet etch process, a dry etch process, or a combination thereof) to remove the nitride layer 520 (e.g., with the upper surface of the semiconductor active layer 116 serving as a stop layer) and to reduce a cross-sectional (i.e., vertical) thickness of the first oxide layer 510. Accordingly, the wet etch process performed at step 818 results in the formation of the insulating spacer 118.

Accordingly, each of the patterned wafers 110, 210, and 210′integrate the low-power devices (e.g., the SW 18 and the LNA 28) and the high-power devices (e.g., the PA 12) onto a single wafer while effectively dissipating heat generated by the high-power devices due to the absence of the insulator layer 114 in the second region 110B. Moreover, the inclusion of the insulator layer 114 in the first regions 110A of the patterned wafer 110, 210, 210′inhibits or reduces leakage currents and enhances noise isolation in the first regions 110A that may otherwise degrade the performance of the transmit/receive switch 18 and the LNA 28.

Additionally, each of the patterned wafers 110 and 210′ include insulating spacers 118 that further enables the wafers to enhance noise isolation and reduce leakage currents between the first portion 116A of the semiconductor active layer 116 and other regions of the patterned wafer 110, thereby improving the signal-to-noise (SNR) ratio of the various circuits thereon, such as the LNA 28.

At least a portion of the techniques of the present invention may be implemented in an integrated circuit. In forming integrated circuits, identical die are typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Any of the exemplary circuits illustrated in the accompanying figures, or portions thereof, may be part of an integrated circuit. Integrated circuits so manufactured are considered part of this invention.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having active semiconductor devices integrated with passive components in accordance with one or more embodiments of the invention.

An integrated circuit in accordance with aspects of the present disclosure can be employed in essentially any application and/or electronic system where high-frequency power semiconductor devices (e.g., RF power amplifiers) are employed. Suitable systems and devices for implementing embodiments of the invention may include, but are not limited to, portable electronics (e.g., cell phones, tablet computers, etc.). Systems incorporating such integrated circuits are considered part of this invention. Given the teachings of the present disclosure provided herein, one of ordinary skill in the art will be able to contemplate other implementations and applications of embodiments of the invention.

The illustrations of embodiments of the invention described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and are not drawn to scale. Accordingly, the specification and drawings are to be regarded in an illustrative rather than a restrictive sense.

Embodiments of the invention are referred to herein, individually and/or collectively, by the term “embodiment” merely for convenience and without intending to limit the scope of this application to any single embodiment or inventive concept if more than one is, in fact, shown.

Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “upper,” “lower” and “back” are used to indicate relative positioning of elements or structures to each other when such elements are oriented in a particular manner, as opposed to defining absolute positioning of the elements.

The corresponding structures, materials, acts, and equivalents of all means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the various embodiments with various modifications as are suited to the particular use contemplated.

The abstract is provided to comply with 37 C.F.R. § 1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus the following claims are hereby incorporated into the Detailed Description, with each claim standing on its own as separately claimed subject matter.

Given the teachings of embodiments of the invention provided herein, one of ordinary skill in the art will be able to contemplate other implementations and applications of the techniques of embodiments of the invention. Although illustrative embodiments of the invention have been described herein with reference to the accompanying drawings, it is to be understood that embodiments of the invention are not limited to those precise embodiments, and that various other changes and modifications are made therein by one skilled in the art without departing from the scope of the appended claims.

1. A patterned silicon-on-insulator (SOI) wafer, comprising:
a semiconductor substrate, an insulator layer, and a semiconductor active layer sequentially stacked in a vertical direction perpendicular to a lower surface of the semiconductor substrate,
wherein the patterned SOI wafer comprises a first region and a second region adjacent to the first region in a horizontal direction parallel to the lower surface of the semiconductor substrate, the first region being configured for low-power devices and the second region being configured for high-power devices,
wherein in the second region, at least a portion of the insulator layer is removed such that the semiconductor active layer is in direct contact with the semiconductor substrate.

2. The patterned SOI wafer of claim 1, wherein the semiconductor substrate and the semiconductor active layer comprise silicon, and wherein the insulator layer comprises an oxide.

3. The patterned SOI wafer of claim 1, wherein a thermal conductivity of the second region is greater than a thermal conductivity of the first region.

4. The patterned SOI wafer of claim 1, further comprising an insulating spacer extending in the vertical direction and on a sidewall of the semiconductor active layer in the first region and contacting the insulator layer, the insulating spacer electrically isolating a first portion of the semiconductor active layer in the first region from a second portion of the semiconductor active layer in the second region.

5. The patterned SOI wafer of claim 4, wherein an upper surface of the insulating spacer is horizontally coplanar with an upper surface of each of the first and second portions of the semiconductor active layer.

6. The patterned SOI wafer of claim 4, wherein a lower surface of the insulating spacer is horizontally coplanar with a lower surface of each of the first portion of the semiconductor active layer, the second portion of the semiconductor active layer, and an upper surface of the insulator layer.

7. The patterned SOI wafer of claim 4, wherein a thickness of the insulating spacer in the vertical direction and a thickness of the insulator layer in the vertical direction are different.

8. A patterned silicon-on-insulator (SOI) wafer, comprising:
a low-power circuit region comprising a semiconductor substrate, an insulator layer on the semiconductor substrate, an insulating spacer on the insulator layer, and a semiconductor active layer on the insulator layer, wherein:
the semiconductor substrate, the insulator layer, and the semiconductor active layer extend in a horizontal direction parallel to a lower surface of the semiconductor substrate, and
the insulating spacer extends in a vertical direction perpendicular to the lower surface of the semiconductor substrate; and
a high-power circuit region comprising the semiconductor substrate and the semiconductor active layer directly on the semiconductor substrate.

9. The patterned SOI wafer of claim 8, wherein a thermal conductivity of the high-power circuit region is greater than a thermal conductivity of the low-power circuit region.

10. The patterned SOI wafer of claim 8, wherein the insulating spacer is on a sidewall of the semiconductor active layer in the low-power circuit region, proximate the high-power circuit region, and contacts the insulator layer, the insulating spacer electrically isolating a first portion of the semiconductor active layer in the low-power circuit region from a second portion of the semiconductor active layer in the high-power circuit region.

11. The patterned SOI wafer of claim 10, wherein an upper surface of the insulating spacer is horizontally coplanar with an upper surface of each of the first and second portions of the semiconductor active layer.

12. The patterned SOI wafer of claim 10, wherein a lower surface of the insulating spacer is horizontally coplanar with a lower surface of the semiconductor active layer and an upper surface of the insulator layer.

13. The patterned SOI wafer of claim 10, wherein a thickness of the insulating spacer in the vertical direction and a thickness of the insulator layer in the vertical direction are different.

14. A front-end module, comprising:
A patterned silicon-on-insulator (SOI) wafer comprising a semiconductor substrate, an insulator layer, and a semiconductor active layer sequentially stacked in a vertical direction perpendicular to a lower surface of the semiconductor substrate, wherein:
the patterned SOI wafer comprises a first region and a second region adjacent to the first region in a horizontal direction parallel to the lower surface of the semiconductor substrate, the first region being configured for low-power devices and the second region being configured for high-power devices, and
in the second region, at least a portion of the insulator layer is removed such that the semiconductor active layer is in direct contact with the semiconductor substrate;
a low noise amplifier in the first region and configured to generate a first output power;
a radio frequency (RF) power amplifier in the second region and configured to generate a second output power; and
a switch in the first region and electrically connected to the low noise amplifier and the RF power amplifier.

15. The front-end module of claim 14, wherein the semiconductor substrate and the semiconductor active layer comprise silicon, and wherein the insulator layer comprises an oxide.

16. The front-end module of claim 14, wherein a thermal conductivity of the second region is greater than a thermal conductivity of the first region.

17. The front-end module of claim 14, further comprising an insulating spacer extending in the vertical direction and on a sidewall of the semiconductor active layer in the first region and contacting the insulator layer, the insulating spacer electrically isolating a first portion of the semiconductor active layer in the first region from a second portion of the semiconductor active layer in the second region.

18. The front-end module of claim 17, wherein an upper surface of the insulating spacer is horizontally coplanar with an upper surface of each of the first and second portions of the semiconductor active layer.

19. The front-end module of claim 17, wherein a lower surface of the insulating spacer is horizontally coplanar with a lower surface of each of the first portion of the semiconductor active layer, the second portion of the semiconductor active layer, and an upper surface of the insulator layer.

20. The front-end module of claim 17, wherein:
the low noise amplifier is configured to amplify receive signals in a receive signal path of the front-end module;
the radio frequency power amplifier is configured to amplify transmit signals in a transmit signal path of the front-end module; and
the switch is configured to control the transmit signal path and/or the receive signal path.

21.-24. (canceled)
